(19) United States
(12) Patent Application Publication
(10) Pub. No.: US 2011/0265723 A1
(43) Pub. Date: Nov. 3, 2011

(54) METAL-ORGANIC CHEMICAL VAPOR DEPOSITION APPARATUS

(75) Inventor: Chun-Te CHIANG, Tainan City (TW)

(73) Assignee: CHI MEI LIGHTING TECHNOLOGY CORP., Tainan City (TW)

(21) Appl. No.: 13/095,910

(22) Filed: Apr. 28, 2011

(30) Foreign Application Priority Data
Apr. 29, 2010 (TW) 99113734

(51) Int. Cl. C23C 16/458; C23C 16/46; C23C 16/455

(52) U.S. Cl. 118/725

(57) ABSTRACT

A metal-organic chemical vapor deposition (MOCVD) apparatus is described. The MOCVD apparatus includes a reaction chamber, a rotation stand, a wafer susceptor, a heater and a shower head. The reaction chamber includes an opening. The rotation stand is disposed within the reaction chamber. The wafer susceptor is disposed on the rotation stand, and the wafer susceptor can rotate by the driving of the rotation stand. The wafer susceptor includes a plurality of polygon-shaped wafer pockets disposed on a surface of the wafer susceptor, and the polygon-shaped wafer pockets are suitable to correspondingly accommodate a plurality of wafers. The heater is disposed under the wafer susceptor and within the rotation stand. The shower head covers the opening of the reaction chamber and introduces a gaseous precursor toward the surface of the wafer susceptor.

### RELATED APPLICATIONS

This application claims priority to Taiwan Application Serial Number 099113734, filed Apr. 29, 2010, which is herein incorporated by reference.

### FIELD OF THE INVENTION

The present invention relates to a chemical vapor deposition (CVD) apparatus, and more particularly, to a metal-organic CVD (MOCVD) apparatus.

### BACKGROUND OF THE INVENTION

In a process of fabricating a light-emitting diode (LED), an epitaxy procedure of each semiconductor layer is a very important step. In the epitaxy procedure of the LED, a MOCVD apparatus is typically used and a wafer susceptor is needed to carry wafers.

Refer to FIG. 1. FIG. 1 is schematic diagram showing a conventional MOCVD apparatus. The conventional MOCVD apparatus 200 mainly includes a reaction chamber 202, a rotation stand 204, a wafer susceptor 206, a heater 208 and a shower head 216.

Epitaxy operations of semiconductor material layers are performed within the reaction chamber 202. The reaction chamber 202 typically has an opening 220, so that a plurality of wafers can be disposed on the wafer susceptor 206 through the opening 220. According to the process requirement, the reaction chamber 202 may be selectively set with at least one exhaust port 222. The exhaust port 222 is usually disposed in the lower part of the reaction chamber 202 for exhausting the redundant gaseous precursor and the waste gas formed in the process. The rotation stand 204 is disposed within the reaction chamber 202. The rotation stand 204 may be composed of a hollow pillar or a crutch structure. The rotation stand 204 can spin around within the reaction chamber 202 according to the process requirements.

The wafer susceptor 206 is used to support and carry a plurality of wafers 212, so that an epitaxy process of the wafers 212 can be performed within the reaction chamber 202. The wafer susceptor 206 is disposed on the rotation stand 204 and is supported by the rotation stand 204. The wafer susceptor 206 can be fixed on the rotation stand 204 by, for example, a wedge fastening method. Therefore, when the rotation stand 204 rotates, the wafer susceptor 206 fixed on the rotation stand 204 can be driven to rotate, thereby further driving the wafers 212 on the wafer susceptor 206 to rotate.

As shown in FIG. 1, the heater 208 is disposed under the wafer susceptor 206 and within the rotation stand 204 to heat the wafers 212 on the wafer susceptor 206.

The operation of the heater 208 is preferably independent of that of the rotation stand 204. That is, the rotating of the rotation stand 204 cannot drive the heater 208 to rotate, so that the process of the wafers 212 is performed while the wafers 212 are uniformly heated by the heater 208.

The shower head 216 is disposed on the reaction chamber 202 and covers the opening 220 of the reaction chamber 202. A lower surface of the shower head 216 includes a plurality of nozzles 217 facing the wafers 212 on the wafer susceptor 206. Therefore, the gaseous precursor 218 flowing into the shower head 216 can be introduced toward the reaction chamber 202 through the nozzles 217, and a deposition step, such as an epitaxy step, is performed on a surface 210 of the wafer susceptor 206 and surfaces of the wafers 212 after the gaseous precursor 218 reacts within the reaction chamber 202. In the conventional design of the wafer susceptor 206, wafer pockets having a diameter of 2 inches are distributed on the whole wafer susceptor 206. The sizes of the wafer pockets are small, so that the wafer pockets can be arranged closely for a larger utilization efficiency of the wafer susceptor.

As the process technology is advanced, the wafer size is gradually increased. For example, in the fabrication of a light-emitting diode, the size of a blue light epitaxial substrate is changed from original 2 inches to current 4 inches. The purpose of increasing the substrate size is to reduce the cost of the subsequent chip processes. However, considering the limitation of the size of the original reaction chamber, the size of the wafer susceptor cannot be enlarged. After the wafer pockets of the wafer susceptor are redrawn for packing wafers of 4 inches, the amount of the wafer pockets of 4 inches on the wafer susceptor is greatly reduced to 7. Refer to FIG. 2. FIG. 2 illustrates a top view of a wafer susceptor arranged with 4 inches wafers. The wafer susceptor 206 is typically composed of a round plate structure. A plurality of wafer pockets 214 are set on the surface 210 of the wafer susceptor 206. The wafer pockets 214 are pockets set on the surface 210 of the wafer susceptor 206 to firmly accommodate the wafers.

In the conventional wafer susceptor 206, each wafer pocket 214 is a round pocket. A gap is unavoidably formed between two adjacent round pockets due to the shape of the wafer pockets 214, so that the wafer pockets 214 cannot be closely arranged on the surface 210 of the wafer susceptor 206. As a result, the area of the surface 210 of the wafer susceptor 206 is wasted, and the wafer susceptor 206 cannot be effectively utilized. The amount of the wafers carried by the wafer susceptor 206 is limited. As a result, the throughput of the light-emitting diodes is decreased, thereby being unfavorable to the mass production.

### SUMMARY OF THE INVENTION

Therefore, one aspect of the present invention is to provide a MOCVD apparatus, in which a wafer susceptor includes a plurality of polygon-shaped wafer pockets. With the property, which the polygon-shaped wafer pockets can be arranged side by side, the polygon-shaped wafer pockets can be closely arranged on a surface of the wafer susceptor. Accordingly, the surface area of the wafer susceptor can be effectively utilized.

Another aspect of the present invention is to provide a MOCVD apparatus, in which an accommodating surface of a wafer susceptor has a high the utilization ratio, so that the amount of wafers accommodated by the wafer susceptor is effectively increased. Therefore, the throughput of light-emitting diodes is increased, and the MOCVD apparatus has superior mass production ability.

According to the aforementioned aspects, the present invention provides a MOCVD apparatus. The MOCVD apparatus includes a reaction chamber, a rotation stand, a wafer susceptor, a heater and a shower head. The reaction chamber includes an opening. The rotation stand is disposed within the reaction chamber. The wafer susceptor is disposed on the rotation stand and the wafer susceptor can rotate by the driving of the rotation stand. The wafer susceptor includes a plurality of polygon-shaped wafer pockets disposed on a surface of the wafer susceptor, and the polygon-shaped wafer pockets are suitable to correspondingly accommodate a plurality of wafers. The heater is disposed under the wafer susceptor and within the rotation stand. The shower head covers the opening of the reaction chamber and introduces a gaseous precursor toward the surface of the wafer susceptor.

According to a preferred embodiment of the present invention, the polygon-shaped wafer pockets have a same shape.

According to another preferred embodiment of the present invention, the polygon-shaped wafer pockets have different shapes.

According to still another preferred embodiment of the present invention, shapes of the polygon-shaped wafer pockets are the same as shapes of the corresponding wafers.

According to further another preferred embodiment of the present invention, at least one side of each of the polygon-shaped wafer pockets is connected with at least one side of the adjacent polygon-shaped wafer pocket.

By placing polygon-shaped wafer pockets that can be closely arranged on a wafer susceptor to accommodate wafers, the utilization ratio of a surface area of the wafer susceptor is greatly increased, thereby increasing the amount of the wafers accommodated by the wafer susceptor. Therefore, the throughput of light-emitting diodes is increased, and the MOCVD apparatus has superior mass production ability.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1 is schematic diagram showing a conventional MOCVD apparatus;

FIG. 2 illustrates a top view of a conventional wafer susceptor;

FIG. 3 is schematic diagram showing a MOCVD apparatus in accordance with a preferred embodiment of the present invention;

FIG. 4 illustrates a top view of a wafer susceptor in accordance with a preferred embodiment of the present invention;

FIG. 5 illustrates a top view of a wafer susceptor in accordance with another preferred embodiment of the present invention; and

FIG. 6 illustrates a top view of a wafer susceptor in accordance with still another preferred embodiment of the present invention.

### DETAILED DESCRIPTION OF THE PREFERRED EMBODIMENT

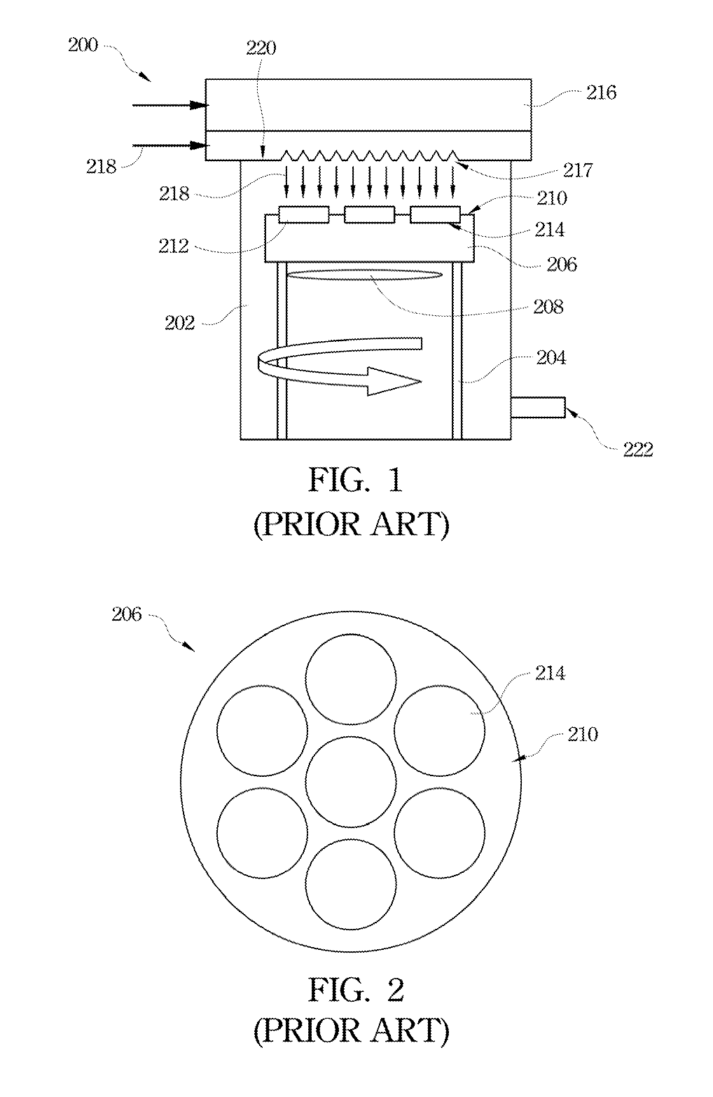

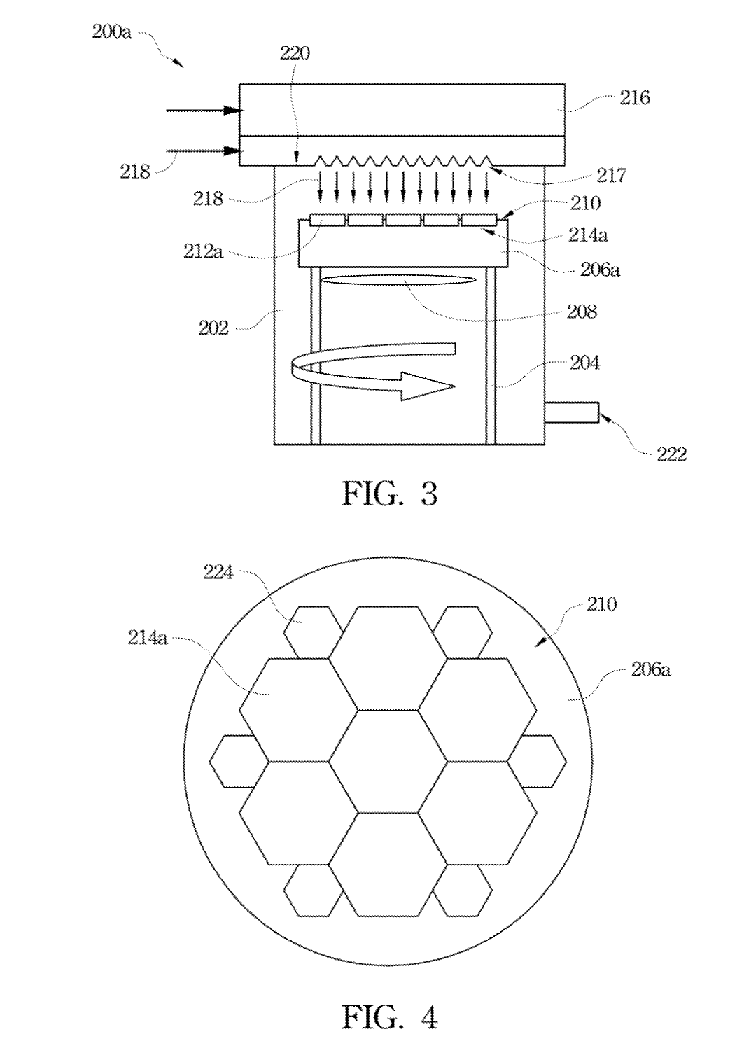

Refer to FIG. 3. FIG. 3 is schematic diagram showing a MOCVD apparatus in accordance with a preferred embodiment of the present invention. A MOCVD apparatus 200a mainly includes a reaction chamber 202, a rotation stand 204, a wafer susceptor 206a, a heater 208 and a shower head 216. The MOCVD apparatus 200a is substantially similar to the MOCVD apparatus 200 shown in FIG. 1. Simultaneously referring to FIG. 2 and FIG. 4, the difference between the MOCVD apparatus 200a and the MOCVD apparatus 200 is that the wafer susceptor 206a of the MOCVD apparatus 200a includes polygon-shaped wafer pockets 214a and 224, which are different from the round wafer pockets 214 on the wafer susceptor 206 of the MOCVD apparatus 200.

In an epitaxy process of a semiconductor material layer of a light-emitting diode, an epitaxy product formed by a chemical reaction within the given reaction chamber 202 is deposited on entire surface of the wafer susceptor 206a. The epitaxy layers deposited on gaps between the wafers cannot be used in the subsequent process, thereby causing a waste. Therefore, while the amount of devices that can be treated in the same reaction chamber space is larger, the manufacturing cost of each device is reduced. Accordingly, the design of the wafer susceptor 206a has influence on the throughput of the devices.

In the present embodiment, a surface 210 of the wafer susceptor 206a includes a plurality of polygon-shaped wafer pockets 214a and 224. The polygon-shaped wafer pockets 214a and 224 are indented in the surface 210 of the wafer susceptor 206a to firmly accommodate wafers 212a for being processed within the reaction chamber 202.

In the embodiment illustrated in FIG. 4, the polygon-shaped wafer pockets 214a and 224 all have a same shape, such as a hexagon. In other embodiments, the polygon-shaped wafer pockets 214a and 224 can have different shapes, such as a hexagon and a triangle. The shapes of the polygon-shaped wafer pockets 214a and 224 may be the same as or different from the shapes of the wafers 212a correspondingly carried by the polygon-shaped wafer pockets 214a and 224. For example, when the polygon-shaped wafer pockets 214a are hexagon pockets, the wafer pockets 214a can accommodate the wafers 212a in hexagon, or other shape, such as quadrangle or round.

In one embodiment, the polygon-shaped wafer pockets are of a same size, i.e. the polygon-shaped wafer pockets have a same dimension and a same shape. In other embodiments, the polygon-shaped wafer pockets may have a same shape and be of at least two different sizes. For example, the polygon-shaped wafer pockets 214a and 224 shown in FIG. 4 have the same shape, and the polygon-shaped wafer pockets 214a are larger than the polygon-shaped wafer pockets 224.

In one embodiment, shapes of the polygon-shaped wafer pockets of the wafer susceptor 206a may be polygons that are beneficial to close arrangement, such as triangles, quadrangles, pentagons, hexagons or octagons. In the present embodiment, in order to utilize the area of the surface 210 of the wafer susceptor 206a more effectively, the polygon-shaped wafer pockets 214a and 224 are closely arranged to make at least one side of each polygon-shaped wafer pocket 214a and 224 be connected with at least one side of the adjacent polygon-shaped wafer pocket 214a and 224, such as shown in FIG. 4.

Simultaneously referring to FIG. 1 and FIG. 3, the gap between any adjacent two of the polygon-shaped wafer pockets 214a and 224 is obviously smaller than the adjacent two of the wafer pockets 214 shown in FIG. 1. Therefore, in comparison with the conventional wafer susceptor 206, the accommodating area of the wafer susceptor 206a of the present embodiment can be utilized more effectively, thereby increasing the production efficiency.

Depths of the polygon-shaped wafer pockets 214a and 224 are preferably less than or equal to thicknesses of the corresponding wafers 212a. As a result, when the wafers 212a are placed on the wafer susceptor 206a, the top surfaces of the wafers 212 may be level with the surface 210 of the wafer susceptor 206a, or may be slightly higher than the surface 210 of the wafer susceptor 206a. Therefore, when a deposition step, such as an epitaxy step, is subsequently performed on the wafers 212a on the wafer susceptor 206a, it can prevent the deposited material from covering sidewalls of the polygon-shaped wafer pockets 214a and 224, thereby can prevent the deposited material on the sidewalls of the polygon-shaped wafer pockets 214a and 224 from obstructing the progress of the process.

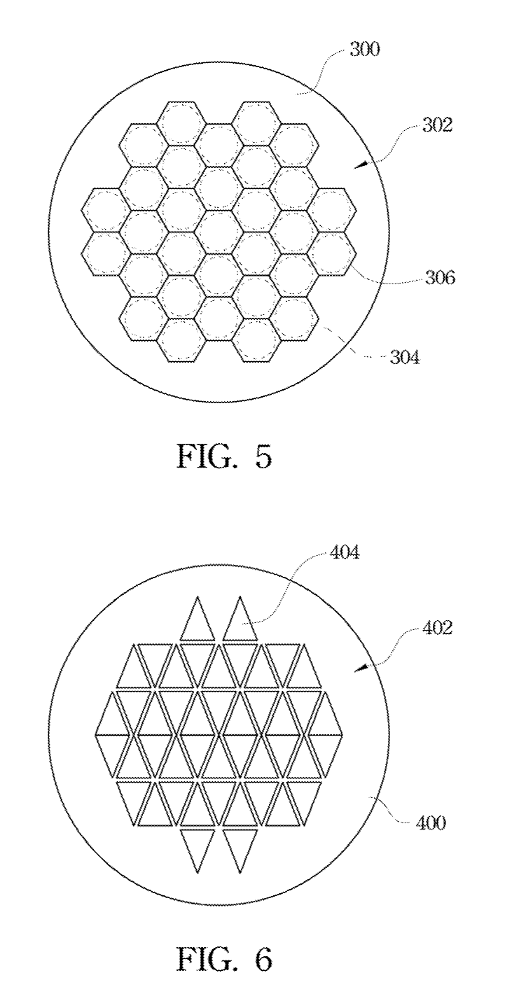

Refer to FIG. 5. FIG. 5 illustrates a top view of a wafer susceptor in accordance with another preferred embodiment of the present invention. In the present embodiment, shapes of polygon-shaped wafer pockets 304 indented in a surface 302 of a wafer susceptor 300 are hexagons. The shapes of the polygon-shaped wafer pockets 304 are circumscribed polygons of corresponding circles 306 indicated by dotted lines in FIG. 5, such as circumscribed hexagons. From FIG. 5, it is known that in comparison with the corresponding circles 306, the design of the polygon-shaped wafer pockets 304 can utilize the accommodating area of the susceptor 300 more effectively. In addition, compared with the embodiment shown in FIG. 4, the hexagons designed in the present embodiment substantially have a same area, and the area of each hexagon is less than the area of each polygon-shaped wafer pocket 214a, for example. Accordingly, the susceptor 300 of the present embodiment has a better area utilization efficiency.

In the present invention, shapes of polygon-shaped wafer pockets of a wafer susceptor may be polygons, each of which has three or more sides. Refer to FIG. 6. FIG. 6 illustrates a top view of a wafer susceptor in accordance with still another preferred embodiment of the present invention. In the present embodiment, shapes of polygon-shaped wafer pockets 304 indented in a surface 402 of a wafer susceptor 400 are triangles.

Take a susceptor having a diameter of 380 mm, which can carry thirty-one pieces of wafers having a diameter of 2 inches, as an example. When the susceptor having the diameter of 380 mm is used to carry thirty-one pieces of wafers having the diameter of 2 inches, the coverage area is 97.3896 square inch. As shown in FIG. 2, when the susceptor is used to carry wafers having a diameter of 4 inches, the coverage area is 87.9648 square inch, which is less than the coverage area achieved by carrying thirty-one pieces of wafers having the diameter of 2 inches, by a ratio of 9.7%. As shown in FIG. 4, when the susceptor is used to carry wafers in a circumscribed hexagon of a circle having a diameter of 4 inches and six pieces of smaller wafers in a similar hexagon, the coverage area increases 20.785 square inch, and the increment of the coverage reaches a ratio of 33%.

According to the aforementioned embodiments of the present invention, one advantage of the present invention is that a wafer susceptor of a MOCVD apparatus of the present invention includes a plurality of polygon-shaped wafer pockets, which can be closely arranged on a surface of the wafer susceptor. Therefore, an epitaxial deposition step is almost all performed on surfaces of wafers, and few epitaxy materials are wasted to form on the gap region of the wafer susceptor. Accordingly, the surface area of the wafer susceptor can be effectively utilized.

According to the aforementioned embodiments of the present invention, another advantage of the present invention is that the utilization ratio of an accommodating surface of a wafer susceptor in a MOCVD apparatus of the present invention is high, thereby effectively increasing the area for accommodating wafers. Therefore, the throughput of light-emitting diodes is increased, the production efficiency is enhanced, and the MOCVD apparatus has superior mass production ability.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A metal-organic chemical vapor deposition apparatus, including:
a reaction chamber including an opening;
a rotation stand disposed within the reaction chamber;
a wafer susceptor disposed on the rotation stand, wherein the wafer susceptor can rotate by the driving of the rotation stand, the wafer susceptor includes a plurality of polygon-shaped wafer pockets disposed on a surface of the wafer susceptor, and the polygon-shaped wafer pockets are suitable to correspondingly accommodate a plurality of wafers;
a heater disposed under the wafer susceptor and within the rotation stand; and
a shower head covering the opening of the reaction chamber and introducing a gaseous precursor toward the surface of the wafer susceptor.

2. The metal-organic chemical vapor deposition apparatus according to claim 1, wherein the polygon-shaped wafer pockets have a same shape.

3. The metal-organic chemical vapor deposition apparatus according to claim 1, wherein the polygon-shaped wafer pockets have different shapes.

4. The metal-organic chemical vapor deposition apparatus according to claim 1, wherein shapes of the polygon-shaped wafer pockets are the same as shapes of the corresponding wafers.

5. The metal-organic chemical vapor deposition apparatus according to claim 1, wherein depths of the polygon-shaped wafer pockets are less than or equal to thicknesses of the corresponding wafers.

6. The metal-organic chemical vapor deposition apparatus according to claim 1, wherein at least one side of each of the polygon-shaped wafer pockets is connected with at least one side of the adjacent polygon-shaped wafer pocket.

7. The metal-organic chemical vapor deposition apparatus according to claim 1, wherein the polygon-shaped wafer pockets are of a same size.

8. The metal-organic chemical vapor deposition apparatus according to claim 1, wherein the polygon-shaped wafer pockets are of at least two different sizes.

9. The metal-organic chemical vapor deposition apparatus according to claim 1, wherein shapes of the polygon-shaped wafer pockets are triangles, quadrangles, pentagons, hexagons or octagons.

10. The metal-organic chemical vapor deposition apparatus according to claim 1, wherein the heater is not driven to rotate by the rotation stand.
